(19) United States
(12) Patent Application Publication
(10) Pub. No.: US 2024/0272327 A1
(43) Pub. Date: Aug. 15, 2024

(54) METHOD AND SYSTEM TO CALIBRATE SUBSURFACE EARTH STRESSES IN A GEOCELLULAR MODEL

(71) Applicant: ExxonMobil Technology and Engineering Company, Spring, TX (US)

(72) Inventors: Brian R. CRAWFORD, The Woodlands, TX (US); Mary K. JOHNS, Houston, TX (US); Kelvin I. AMALOKWU, Houston, TX (US); Christopher J. FINN, Missouri City, TX (US)

(21) Appl. No.: 18/411,288

(22) Filed: Jan. 12, 2024

Related U.S. Application Data
(60) Provisional application No. 63/484,311, filed on Feb. 10, 2023.

(51) Int. Cl. G01V 20/00; G06F 30/13

(52) U.S. Cl. CPC G01V 20/00; G06F 30/13

(57) ABSTRACT

A methodology for estimating stresses in the subsurface for the generation of a three dimensional (3D) mechanical earth model is provided. The method is executed via a processor of a computing system. The method includes generating a synthetic principal horizontal stress profile representative of a one-dimensional mechanical earth model (1D MEM) based on simplification that all formations are elastically isotropic. The method also includes combining the isotropically generated synthetic principal horizontal stress profile with an additional data-driven functional relationship for anisotropic formations to generate a global predictive conditional relationship based on a lithology dependent cutoff. The method also further includes generating a three-dimensional volume-based mechanical earth model using the global predictive conditional relationship.

### CROSS-REFERENCE TO RELATED APPLICATION

This application claims priority to and the benefit of U.S. Provisional Application No. 63/484,311, entitled “METHOD AND SYSTEM TO CALIBRATE SUBSURFACE EARTH STRESSES IN A GEOCELLULAR MODEL,” having a filing date of Feb. 10, 2023, the disclosure of which is incorporated herein by reference in its entirety.

### FIELD OF THE INVENTION

The present application relates generally to the field of hydrocarbon exploration, development and production. Specifically, the disclosure relates to a methodology for the generation and calibration of geocellular models to represent subsurface earth stresses.

### BACKGROUND OF THE INVENTION

This section is intended to introduce various aspects of the art, which may be associated with exemplary embodiments of the present disclosure. This discussion is believed to assist in providing a framework to facilitate a better understanding of particular aspects of the present disclosure. Accordingly, it should be understood that this section should be read in this light, and not necessarily as admissions of prior art.

The in-situ state of stress is fundamental to all subsurface geomechanics and rock engineering endeavors. In particular, predicting layer-to-layer variation of horizontal principal stress magnitudes is useful in a wide range of energy-related applications. For example, such predictions may be used in calculating wellbore stability while drilling. Similarly, these predictions may be used in completions, specifically for hydraulic fracturing. In addition, these predictions are useful in calculating mechanical seal capacity and caprock integrity in the applications of underground gas storage, carbon capture, utilization and storage. Moreover, such predictions are also used for infill drilling and field development for calculating parent-child well interactions, and depletion planning. In addition, the predictions are useful in abandonment for the analysis of annular barriers.

As one example, stresses and how they vary in the Earth are useful for understanding hydraulic fractures. In particular, where stresses are high, such stresses can impede the development of hydraulic fractures. Hydraulic fractures, also known as fracking, involves putting a well in the Earth and inducing fractures in the Earth. Understanding stresses in the Earth thus provides a sense of hydraulic fracture size and shape.

Stress is a tensor quantity and subsurface Earth stresses can be represented by three orthogonal principal stresses, a vertical overburden stress and a maximum and a minimum horizontal stress. The conventional way of calculating horizontal stresses is most often informed by a multiplicity of detailed information involving data derived from the integration of core and well logs, including an estimate of mineralogy, and may include an estimate of tectonic strains.

The calculation of subsurface stress may be calibrated by direct measurements. For example, the magnitude of the minimum principal horizontal stress (S_{HMIN}) can be directly measured in the subsurface through identification of the closure pressure after shut-in of a diagnostic fracture injection test (DFIT). As one example, the DFIT, also referred to as a minifrac test, may involve the pumping of a relatively small volume of water into a short wellbore interval over a brief period of time. The magnitude of the maximum principal horizontal stress (S_{HMAX}) can be inferred from image log analysis of compressional (breakouts) and tensile (drilling induced tensile fractures) failures of the borehole wall. However, neither of these methods is conducted at a sufficiently high frequency or fine-scale to enable adequate characterization of horizontal stress magnitude variation with depth as required for practical engineering applications. In particular, the DFIT provides an estimate of the stresses in the Earth, which can be used to calibrate stress curves derived from logs. The addition of a tectonic strain term in the stress calculations results in a shift of the curve, which may be adjusted to more closely approximate the DFIT stress measurement where the amount of shifting required depends on the state of stress in the Earth. Thus, current methods may use the mineralogy logs and tectonic strain, which include a lot of uncertainty. In particular, the mineralogy logs are used to calculate Biot's coefficient which in turn informs the poroelastic part of the stress estimation procedure. In particular, logs with sufficient mineralogic detail may not be available everywhere, so that Biot's coefficient cannot be adequately calculated resulting in the tectonic strain shift becoming only a rough estimate leading to significant predictive inaccuracies.

The estimated stress profile may be used to help estimate the size of the fractures. For example, given a lateral well and knowledge of where fractures were taller, or perhaps more height constrained in different areas, such knowledge may enable an estimate of the optimum number of wells to use. As one example, if a fracture grows very tall or very extensively, then that information could be useful to determine the number of wells and the spacing of the wells.

### SUMMARY OF THE INVENTION

In one or some embodiments, a method for calibrating three-dimensional earth models is disclosed. The method can be executed via a processor of a computing system. The method includes generating a synthetic principal horizontal stress profile representative of a one-dimensional mechanical earth model (1D MEM) based on a simplification that all formations are elastically isotropic. The method includes combining the isotropically generated synthetic principal horizontal stress profile with an additional data-driven functional relationship for anisotropic formations to generate a global predictive conditional relationship based on a lithology dependent cutoff. The method includes generating a three-dimensional volume-based mechanical earth model using the global predictive conditional relationship.

In one or some embodiments, a method for generating and propagating synthetic stress profiles is disclosed. The method can be executed via a processor of a computing system. The method includes generating a synthetic principal horizontal stress profile representative of a one-dimensional mechanical earth model (1D MEM) based on a simplification that all formations are elastically isotropic. The method includes combining the isotropically generated synthetic principal horizontal stress profile with an additional data-driven functional relationship for anisotropic formations to generate a global predictive conditional relationship based on a lithology dependent cutoff. The method includes propagating the isotropically generated synthetic principal horizontal stress profile through a 3D geocellular model based on the global predictive conditional relationship to generate a 3D synthetic principal horizontal stress profile geomodel.

### BRIEF DESCRIPTION OF THE DRAWINGS

The present application is further described in the detailed description which follows, in reference to the noted plurality of drawings by way of non-limiting examples of exemplary implementations, in which like reference numerals represent similar parts throughout the several views of the drawings. In this regard, the appended drawings illustrate only exemplary implementations and are therefore not to be considered limiting of scope, for the disclosure may admit to other equally effective embodiments and applications.

FIG. 1 is a process flow diagram of an exemplary method for generating an estimation of stresses with depth, in accordance with the present techniques;

FIG. 2A is a graph of a single function relationship between a log-derived static anisotropic S_{HMIN} gradient and a dynamic Young's modulus;

FIG. 2B is a graph of optimization of all calibration constants through linear regression;

FIG. 3 is a schematic view of an exemplary method for generating a three-dimensional geocellular model based on facies clay content in accordance with the present techniques;

FIG. 4 is a block diagram of an exemplary cluster computing system that may be utilized to implement the present techniques; and

FIG. 5 is a block diagram of an exemplary non-transitory, computer-readable storage medium that may be used for the storage of data and modules of program instructions for implementing the present techniques.

It should be noted that the figures are merely examples of the present techniques and are not intended to impose limitations on the scope of the present techniques. Further, the figures are generally not drawn to scale, but are drafted for purposes of convenience and clarity in illustrating various aspects of the techniques.

### DETAILED DESCRIPTION OF THE INVENTION

The methods, devices, systems, and other features discussed below may be embodied in a number of different forms. Not all of the depicted components may be required, however, and some implementations may include additional, different, or fewer components from those expressly described in this disclosure. Variations in the arrangement and type of the components may be made without departing from the spirit or scope of the claims as set forth herein. Further, variations in the processes described, including the addition, deletion, or rearranging and order of logical operations, may be made without departing from the spirit or scope of the claims as set forth herein.

It is to be understood that the present disclosure is not limited to particular devices or methods, which may, of course, vary. It is also to be understood that the terminology used herein is for the purpose of describing particular embodiments only, and is not intended to be limiting. As used herein, the singular forms “a,” “an,” and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected. The word “exemplary” is used herein to mean “serving as an example, instance, or illustration.” Any aspect described herein as “exemplary” is not necessarily to be construed as preferred or advantageous over other aspects. The term “uniform” means substantially equal for each sub-element, within about ±10% variation.

The term “and/of” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “including,” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the term “any” means one, some, or all of a specified entity or group of entities, indiscriminately of the quantity.

The phrase “at least one,” when used in reference to a list of one or more entities (or elements), should be understood to mean at least one entity selected from any one or more of the entities in the list of entities, but not necessarily including at least one of each and every entity specifically listed within the list of entities, and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently, “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” may mean A alone, B alone, C alone, A and B together, A and C together, B and C together, A, B, and C together, and optionally any of the above in combination with at least one other entity.

As used herein, the phrase “based on” does not mean “based only on,” unless expressly specified otherwise. In other words, the phrase “based on” means “based only on,” “based at least on,” and/or “based at least in part on.”

The term “enhanced oil recovery” (EOR) refers to processes for enhancing the recovery of hydrocarbons (e.g., primarily oil) from subterranean reservoirs through the introduction of materials not naturally occurring in the reservoir. Examples of EOR techniques include gas injection, chemical flooding, and thermal recovery. Of particular relevance to the present techniques, gas injection involves injecting gas (e.g., natural gas, nitrogen, and/or carbon dioxide) into a reservoir to increase the flow of oil from the reservoir. Moreover, in some cases, liquid may additionally or alternatively be injected into the formation during such techniques. Therefore, the term “fluid injection” is used herein to refer generally to EOR techniques involving the injection of fluids into a formation.

As used herein, the terms “example,” exemplary,” and “embodiment,” when used with reference to one or more components, features, structures, or methods according to the present techniques, are intended to convey that the described component, feature, structure, or method is an illustrative, non-exclusive example of components, features, structures, or methods according to the present techniques. Thus, the described component, feature, structure, or method is not intended to be limiting, required, or exclusive/exhaustive; and other components, features, structures, or methods, including structurally and/or functionally similar and/or equivalent components, features, structures, or methods, are also within the scope of the present techniques.

The term “formation” refers to a subsurface region including an aggregation of subsurface sedimentary, metamorphic and/or igneous matter, whether consolidated or unconsolidated, and other subsurface matter, whether in a solid, semi-solid, liquid and/or gaseous state, related to the geological development of the subsurface region. A formation can be a body of geologic strata of predominantly one type of rock or a combination of types of rock, or a fraction of strata having substantially common sets of characteristics. A formation can contain one or more hydrocarbon-bearing intervals, generally referred to as “reservoirs.” Note that the terms “formation,” “reservoir,” and “interval” may be used interchangeably, but may generally be used to denote progressively smaller subsurface regions, stages, or volumes. More specifically, a “formation” may generally be the largest subsurface region, while a “reservoir” may generally be a hydrocarbon-bearing stage or interval within the geologic formation that includes a relatively high percentage of oil and gas. Moreover, an “interval” may generally be a sub-region or portion of a reservoir.

The term “fracture” refers to a crack or surface of breakage induced by an applied pressure or stress within a subsurface formation.

The term “geophysical data” as used herein broadly includes seismic data, as well as other data obtained from non-seismic geophysical methods such as electrical resistivity. In this regard, examples of geophysical data include, but are not limited to, seismic data, gravity surveys, magnetic data, electromagnetic data, well logs, image logs, radar data, or temperature data.

The term “geological features” (interchangeably termed geo-features) as used herein broadly includes attributes associated with a subsurface, such as any one, any combination, or all of: subsurface geological structures (e.g., channels, volcanos, salt bodies, geological bodies, geological layers, etc.); boundaries between subsurface geological structures (e.g., a boundary between geological layers or formations, etc.); or structure details about a subsurface formation (e.g., subsurface horizons, subsurface faults, mineral deposits, bright spots, salt welds, distributions or proportions of geological features (e.g., lithotype proportions, facies relationships, distribution of petrophysical properties within a defined depositional facies), etc.). In this regard, geological features may include one or more subsurface features, such as subsurface fluid features, that may be hydrocarbon indicators (e.g., Direct Hydrocarbon Indicator (DHI)).

Generally speaking, the term “pressure” refers to a force acting on a unit area. Pressure is typically provided in units of pounds per square inch (psi).

The terms “velocity model,” “density model,” “physical property model,” or other similar terms as used herein refer to a numerical representation of parameters for subsurface regions. Generally, the numerical representation includes an array of numbers, typically a 2-D or 3-D array, where each number, which may be called a “model parameter,” is a value of velocity, density, or another physical property in a cell, where a subsurface region has been conceptually divided into discrete cells for computational purposes. For example, the spatial distribution of velocity may be modeled using constant-velocity units (layers) through which ray paths obeying Snell's law can be traced. A 3-D geologic model (particularly a model represented in image form) may be represented in volume elements (voxels), in a similar way that a photograph (or 2-D geologic model) may be represented by picture elements (pixels). Such numerical representations may be shape-based or functional forms in addition to, or in lieu of, cell-based numerical representations.

The term “seismic data” as used herein broadly means any data received and/or recorded as part of the seismic surveying and interpretation process, including displacement, velocity and/or acceleration, pressure and/or rotation, wave reflection, and/or refraction data. “Seismic data” is also intended to include any data (e.g., seismic image, migration image, reverse-time migration image, pre-stack image, partially-stack image, full-stack image, post-stack image or seismic attribute image) or interpretation quantities, including geophysical properties such as one or more of: elastic properties (e.g., P and/or S wave velocity, P-Impedance, S-Impedance, density, attenuation, anisotropy and the like); and porosity, permeability or the like, that the ordinarily skilled artisan at the time of this disclosure will recognize may be inferred or otherwise derived from such data received and/or recorded as part of the seismic surveying and interpretation process. Thus, this disclosure may at times refer to “seismic data and/or data derived therefrom,” or equivalently simply to “seismic data.” Both terms are intended to include both measured/recorded seismic data and such derived data, unless the context clearly indicates that only one or the other is intended. “Seismic data” may also include data derived from traditional seismic (e.g., acoustic) data sets in conjunction with other geophysical data, including, for example, gravity plus seismic; gravity plus electromagnetic plus seismic data, etc. For example, joint-inversion utilizes multiple geophysical data types.

The term “substantially,” when used in reference to a quantity or amount of a material, or a specific characteristic thereof, refers to an amount that is sufficient to provide an effect that the material or characteristic was intended to provide. The exact degree of deviation allowable may depend, in some cases, on the specific context.

The term “subsurface model” as used herein refer to a numerical, spatial representation of a specified region or properties in the subsurface.

The term “geologic model” as used herein refer to a subsurface model that is aligned with specified geological feature such as faults and specified horizons.

As used herein, “hydrocarbon management”, “managing hydrocarbons” or “hydrocarbon resource management” includes any one, any combination, or all of the following: hydrocarbon extraction; hydrocarbon production, (e.g., drilling a well and prospecting for, and/or producing, hydrocarbons using the well; and/or, causing a well to be drilled, e.g., to prospect for hydrocarbons); hydrocarbon exploration; identifying potential hydrocarbon-bearing formations; characterizing hydrocarbon-bearing formations; identifying well locations; determining well injection rates; determining well extraction rates; identifying reservoir connectivity; acquiring, disposing of, and/or abandoning hydrocarbon resources; reviewing prior hydrocarbon management decisions; and any other hydrocarbon-related acts or activities, such activities typically taking place with respect to a subsurface formation. The aforementioned broadly include not only the acts themselves (e.g., extraction, production, drilling a well, etc.), but also or instead the direction and/or causation of such acts (e.g., causing hydrocarbons to be extracted, causing hydrocarbons to be produced, causing a well to be drilled, causing the prospecting of hydrocarbons, etc.). Hydrocarbon management may include reservoir surveillance and/or geophysical optimization. For example, reservoir surveillance data may include, well production rates (how much water, oil, or gas is extracted over time), well injection rates (how much water or CO₂ is injected over time), well pressure history, and time-lapse geophysical data. As another example, geophysical optimization may include a variety of methods geared to find an optimum model (and/or a series of models which orbit the optimum model) that is consistent with observed/measured geophysical data and geologic experience, process, and/or observation.

As used herein, “obtaining” data generally refers to any method or combination of methods of acquiring, collecting, or accessing data, including, for example, directly measuring or sensing a physical property, receiving transmitted data, selecting data from a group of physical sensors, identifying data in a data record, and retrieving data from one or more data libraries.

The term “wellbore” refers to a borehole drilled into a subterranean formation. The borehole may include vertical, deviated, highly deviated, and/or horizontal sections. The term “wellbore” also includes the downhole equipment associated with the borehole, such as the casing strings, production tubing, gas lift valves, and other subsurface equipment. Relatedly, the term “hydrocarbon well” (or simply “well”) includes the wellbore in addition to the wellhead and other associated surface equipment.

If there is any conflict in the usages of a word or term in this specification and one or more patent or other documents that may be incorporated herein by reference, the definitions that are consistent with this specification should be adopted for the purposes of understanding this disclosure.

### Overview

Due to limitations accompanying direct subsurface measurement of horizontal principal stress magnitudes, a range of model-driven approaches have been developed in order to predict theoretical variability of subsurface stresses with rock type and depth, referred to herein as stress profiles. The most practical stress profiles utilize well log data as input to inform the stress profile prediction workflow. The industry standard method assumes that horizontal stresses are gravity-driven and pore pressure-driven as a consequence of uniaxial vertical compaction under a zero lateral strain boundary condition. This standard method uses linear poroelastic theory (isotropic, anisotropic, or orthotropic symmetry where applicable) to generate an initial uncalibrated stress profile prediction. The initial prediction can then be augmented to account for additional components of horizontal stress resulting from tectonic deformation (finite strains) in order to calibrate the initial prediction to any direct subsurface measurements. In a similar fashion, these theoretical models can be extended to include thermoelastic strains to better approximate the effects of burial history and viscoplastic processes to account for stress relaxation over geological time.

While a range of theoretical models can therefore be used to predict variability of horizontal stress magnitudes with depth in layered formations, all of these theoretical models assume prior knowledge of the weight of the overburden rock and the pore pressure. These theoretical models require lithology-dependent mechanical rock properties as input and some degree of direct subsurface stress measurement for calibration purposes.

Well-based integration of all requisite log, core and subsurface measurement data into a one-dimensional (1D) mechanical earth model (MEM) represents the preferred platform for transforming log-derived (dynamic) to core-derived (static) mechanical properties measurements, and for calibrating theoretical stress predictions to subsurface measurements. For example, assuming the poroelastic model of horizontal stress development, dynamic elastic properties calculated from acoustic and density logs can first be transformed to equivalent anisotropic static values by calibrating to core plug measurements. Then, established petrophysical workflows for determining formation composition can be used to further calculate anisotropic poroelastic properties from formation mineralogy and the static elastic properties using well known theoretical poroelastic relationships. As one example, the anisotropic poroelastic properties many include Biot's coefficient in the vertical and horizontal directions. Initial stress profile predictions can subsequently be mapped to direct in situ measurements through appropriate adjustment of the tectonic strain component. An equivalent workflow could also be employed to derive horizontal stress magnitudes using the viscoplastic stress relaxation model, however in this instance formation mineralogy and static elastic properties would be used for empirical prediction of material creep parameters describing time dependent deformation.

As one specific example, a conventional workflow may calculate horizontal stress magnitudes from well data. In particular, for an anisotropic poroelastic formation in which total principal horizontal stresses arise from gravity (overburden and pore pressure) loading in the vertical (z) direction with additional stress components resulting from tectonic straining in the horizontal (x-y) plane, the minimum (S_{HMIN}) and maximum (S_{HMAX}) subsurface stresses can be calculated according to equations:

$${S}_{HMIN} = [ \frac{{E}_{H}}{{E}_{V}} \frac{{v}_{V}}{1 - {v}_{H}} ( {S}_{OVB} - {α}_{V} {P}_{RES} ) + {α}_{H} {P}_{RES} ] + [ \text{} \frac{{E}_{H}}{1 - {v}_{{H}^{2}}} {ε}_{HMIN} + \frac{{E}_{H} {v}_{H}}{1 - {v}_{{H}^{2}}} {ε}_{HMAX} ] \qquad Eq . 1$$

$${S}_{HMIN} = [ \frac{{E}_{H}}{{E}_{V}} \frac{{v}_{V}}{1 - {v}_{H}} ( {S}_{OVB} - {α}_{V} {P}_{RES} ) + {α}_{H} {P}_{RES} ] + [ \text{} \frac{{E}_{H}}{1 - {v}_{{H}^{2}}} {ε}_{HMAX} + \frac{{E}_{H} {v}_{H}}{1 - {v}_{{H}^{2}}} {ε}_{HMIN} ] \qquad Eq . 2$$

where S_{OVB} refers to overburden stress, PRES represents reservoir pore pressure, E represents Young's modulus, ν represents Poisson's ratio, a represents Biot's coefficient, ε_{HMIN} represents the minimum principal horizontal strain, ε_{HMAX} represents the maximum principal horizontal strain, and subscript “V” represents vertical direction and subscript “H” represents the horizontal direction. A typical 1D wireline log-based workflow might use acoustic and density logs to first determine isotropic dynamic (relatively high frequency, low strain magnitude) elastic properties (Young's modulus E_{DYN} and Poisson's ratio ν_{DYN}). These properties are then calibrated to direct core plug measurements of anisotropic static (relatively low frequency, high strain magnitude) elastic properties (Young's modulus E_{V}, E_{H} and Poisson's ratio ν_{V}, ν_{H}). Mineralogical composition may be typically determined from either elemental spectroscopy logs or through multimineral inversion of “quad-combo” logs (gamma ray, resistivity, neutron-density, photo electric factor and compressional and shear slowness) is then combined with the static elastic properties to calculate associated lithology-dependent anisotropic poroelastic properties (Biot's coefficient α_{V}, α_{H}). Static anisotropic elastic and poroelastic properties logs can then be combined with pore pressure (from direct downhole measurement or various log- and drilling-based prediction techniques) and overburden stress (most often quantified through density log integration) magnitudes according to the first term in brackets in Eqs. 1 and 2 to derive an initial, uncalibrated horizontal stress versus depth profile. Direct measurement of subsurface S_{HMIN}-magnitude (typically from DFITs) can then be used to adjust the initial uncalibrated prediction into congruency with these direct subsurface measurements by optimizing the ε_{HMIN} and ε_{HMAX} tectonic strain constants in the second bracketed term of Eq. 1 to generate a final calibrated S_{HMIN} profile. Implementation of these same calibrated tectonic strain constants in Eq. 2 enables generation of an equivalent S_{HMAX} profile. Alternatively, direct quantification of S_{HMAX}-magnitude could be used to match the initial uncalibrated stress prediction to direct subsurface measurements by optimizing the ε_{HMIN} and ε_{HMAX} tectonic strain constants in the second bracketed term of Eq. 2 to generate a final calibrated S_{HMAX} profile. For example, the direct quantification of S_{HM}AX-magnitude may be typically received from borehole breakout and/or drilling induced tensile fracture analyses incorporating image logs and formation strength. Incorporating these same calibrated tectonic strain constants in Eq. 1 then enables generation of an equivalent S_{HMIN} profile.

However, whereas 1D MEMs may be useful for providing the elastic properties and horizontal stress profiles as required for example by hydraulic fracturing simulation tools, three-dimensional volume-based mechanical earth models (3D MEMs) may be better suited for other applications. For example, 3D MEMs are better suited to predict variability in mechanical rock properties and subsurface stresses away from high data density diagnostic pilot areas, where drainage volumes, well spacing and stacking patterns are known and optimized. 3D MEMs are also better suited to establish criteria for recalibration, such as for pilot triggers. Conventional log-based workflow for deriving stress profiles in 1D MEMs can theoretically be directly applied to 3D MEMs. In practice, however, it is difficult to estimate accurately all the necessary input parameters away from a well. In particular, the full mineralogy as needed to estimate either Biot's coefficients necessary to poroelastic stress prediction or creep parameters as required by viscoplastic stress prediction is prone to large uncertainty away from well control. Furthermore, with sub-optimal knowledge of poroelastic or time-dependent material properties, any subsequent calibration to direct subsurface S_{HMIN} and/or S_{HMAX} measurements is further compromised within the 3D volume.

Moreover, although traditional finite and discrete element 3D mechanical earth modeling techniques can provide full description of the stress tensor that includes principal stress magnitudes and directions throughout the volume of interest, such techniques are highly specialized and can be time consuming to build, maintain quality control (QC), initialize, run and interpret. Furthermore, such techniques may require considerable upscaling of the fine-scale heterogeneity oftentimes encountered in unconventional resources, such as shale gas and tight oil.

Alternatively, principal stress magnitudes can effectively be treated as scalar quantities and propagated as a rock property throughout a 3D cellular geologic model. In the latter case, such 3D MEMs are oftentimes seismic-driven and calibrated to 1D MEMs. However considerable errors in 3D horizontal principal stress magnitude prediction can result if the conventional 1D MEM workflow as detailed above is applied directly to the 3D MEM for the following reasons. First, the quantitative mineralogy required to calculate lithology-dependent anisotropic poroelastic properties (Biot's coefficient α_{V}, α_{H}) is difficult to determine from seismic inversion and difficult to extrapolate beyond well control. Second, without adequately constrained lithology-dependent Biot's coefficients, it is difficult to calibrate an initial horizontal principal stress magnitude estimate (first bracketed term in Eqs. 1 and 2) to direct subsurface DFIT measurements of S_{HMIN} (second bracketed term in Eq. 1) or direct subsurface image log-based calculations of S_{HMAX} (second bracketed term in Eq. 2) throughout a 3D volume.

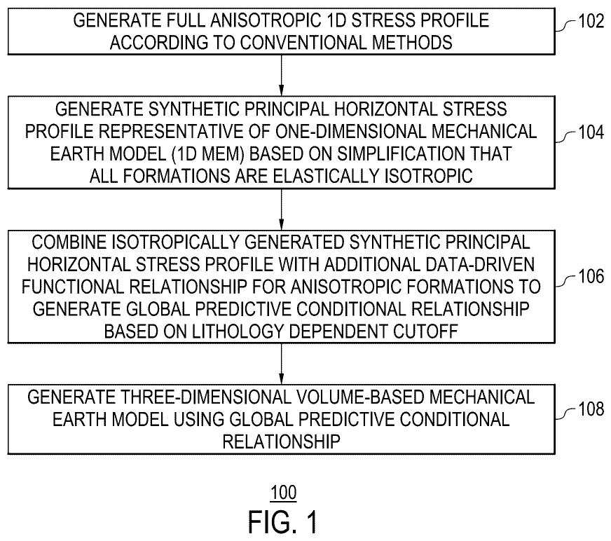

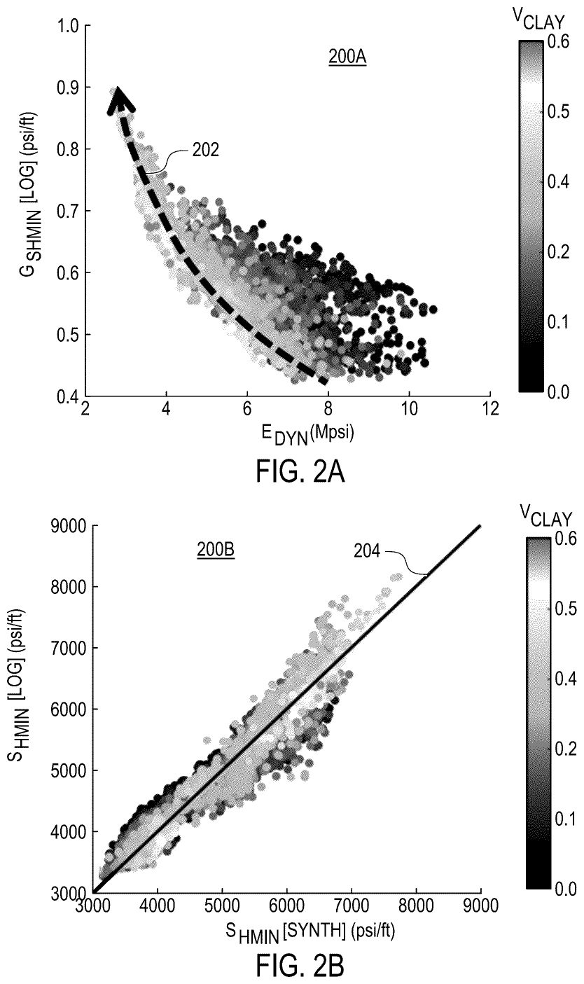

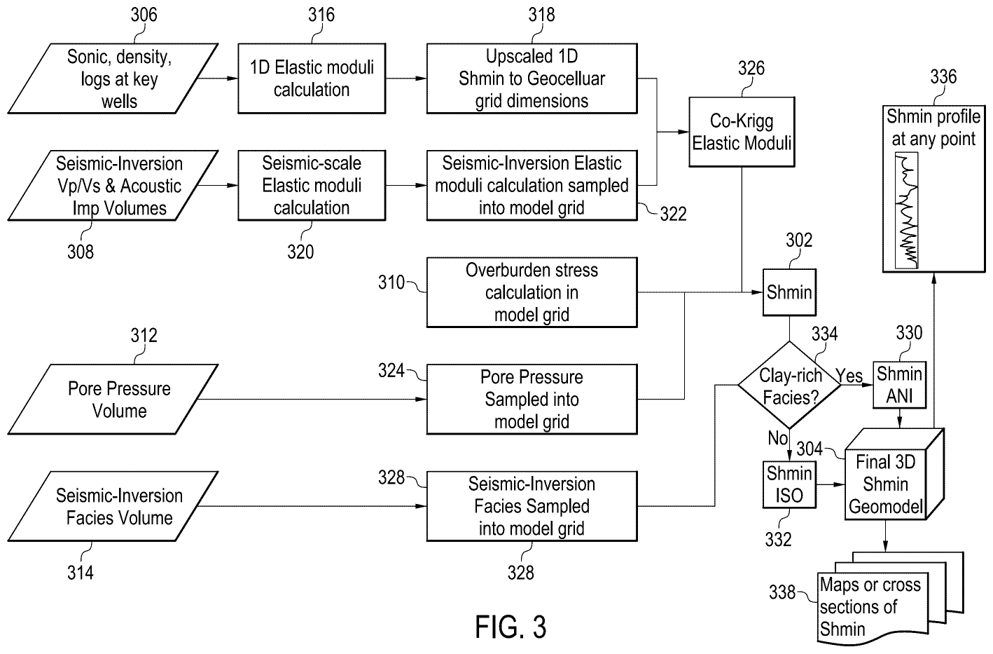

Accordingly, the present techniques solve these problems by providing a simplified calculation procedure for determining horizontal principal stress magnitudes that is both calibrated at key wells and which requires neither complex, mineralogy-dependent poroelastic or creep mechanical properties nor any subsequent tectonic strain correction to directly measured in-situ stress values. This calculation procedure can be implemented in a geocellular mechanical earth model (3D MEM) leveraging a seismic-based facies description to populate a poroelastic-(isotropic or anisotropic) or viscoplastic-derived horizontal stress. In various embodiments, the techniques may include two parts. In the first part, a 1D calibration procedure may be executed for generating synthetic stress profiles at key wells. Examples of such a 1D calibration procedure is described with respect to FIGS. 1 and 2. In the second part, these synthetic stress profiles may be propagated throughout a 3D geocellular model. An example workflow for propagating these synthetic stress profiles throughout a 3D geocellular model is described with respect to FIG. 3.

The present techniques may derive one or more benefits. First, the present techniques enable the use of seismic data for elastic property estimation, allowing estimation away from well log control. The calibration constants described herein together with elastic properties (Young's modulus and Poisson's ratio) are used as input to a stress estimation, away from the detailed well log information. Additionally, embodiments described herein employ rock type, also referred to herein as facies, from seismic data, away from the well. Second, the methodology provides a simplified means of creating a synthetic stress profile, which can be propagated in a 3D model conditionally for isotropic formations or anisotropic formations, according to the seismic-scale facies. For example, similar calculations can be propagated laterally to result in a layered earth, and a model, and at any cell location in the model, the same calculation can be repeated. By using this simpler calculation, the methodology is not as dependent on all the well log-based mineralogical descriptions, static-to-dynamic property conversion, or estimates of tectonic strain, so also are more efficient. The present techniques thus simplify the estimate of the stresses away from well control, and these stresses could serve as input to enable a more efficient and accurate prediction of hydraulic fracture geometries and dimensions. In various embodiments, the simplified model described herein, whether 1D or 3D, with some of the simplifying assumptions described herein, can be used in areas where exact mineralogy is lacking, or not enough well test data exist to constrain, or to extrapolate over a broader region, whether the broader regions is a development pad or many miles.

### Well Calibration Techniques

FIG. 1 is a schematic view of an exemplary method for generating an estimation of stresses with depth, in accordance with the present techniques. In particular, to overcome the perceived inadequacy in horizontal principal stress magnitude prediction throughout a three-dimensional volume-based mechanical earth model (3D MEM), a modified workflow may be used when calibrating a seismic-driven 3D MEM to a log-based 1D MEM. The method may start at block 102, where full anisotropic 1D stress profile is generated according to conventional methods. For example, the 3D MEM may be associated with an unconventional resource application, such as fracking, or an injection, or a carbon storage application, among other various applications using 3D MEMs.

At block 104, a synthetic principal horizontal stress profile representative of a one-dimensional mechanical earth model (1D MEM) is generated based on a simplification that all formations are elastically isotropic. For example, a synthetic S_{HMIN} profile is generated based on simplification that all formations are elastically isotropic and static properties are equivalent to dynamic properties, and assumption that Biot's coefficient equals unity and minimum and maximum tectonic strains are equivalent. For example, starting from a full (static and anisotropic) log-based S_{HMIN} prediction as given by Eq. 1, a first simplification may be made such that all formations are elastically isotropic and static properties are equivalent to dynamic properties whereby E_{H}=E_{V}=E_{DYN} and ν_{H}=ν_{V}=ν_{DYN} and Biot's coefficient equals unity so α_{V}=α_{H}=1 so that:

$${S}_{HMIN} = \frac{{v}_{DYN}}{1 - {v}_{DYN}} ( {S}_{OVB} - α {P}_{RES} ) + α {P}_{RES} + \text{} \frac{{E}_{DYN}}{1 - {v}_{{DYN}^{2}}} {ε}_{HMIN} + \frac{{E}_{DYN} {v}_{DYN}}{1 - {v}_{{DYN}^{2}}} {ε}_{HMAX} \qquad Eq . 3$$

Further, an assumption may be made that minimum and maximum tectonic strains are equivalent so ε_{HMIN}=ε_{HMAX}=ε so that:

$$\frac{{E}_{DYN}}{1 - {v}_{{DYN}^{2}}} ( ε + {v}_{DYN} ε ) = \frac{{E}_{DYN} ε ( 1 + {v}_{DYN} )}{1 - {v}_{{DYN}^{2}}} = \frac{{E}_{DYN} ε}{1 - {v}_{DYN}} \qquad Eq . 4$$

This simplification and assumption can be used to generate a synthetic S_{HMIN} profile equivalent to the full log-based and calibrated prediction as given by Eq. 1 and related through a single global calibration constant C:

$${S}_{HMIN} = \frac{{v}_{DYN}}{1 - {v}_{DYN}} ( {S}_{OVB} - {P}_{RES} ) + {P}_{RES} + \frac{EC}{1 - {v}_{DYN}} \qquad Eq . 5$$

At block 106, the isotropically generated synthetic principal horizontal stress profile is combined with an additional data-driven functional relationship for anisotropic formations to generate a global predictive conditional relationship based on a lithology dependent cutoff. For example, a synthetic S_{HMIN} profile can be combined with an inverse power law to generate a global predictive conditional relationship based on facies clay content. By itself, Eq. 5 is only valid for predicting S_{HMIN}-magnitude in isotropic formations, a different gradient prediction is used for anisotropic formations. However, poroelastic anisotropy is primarily driven by relatively high clay mineral content. Moreover, a single function (inverse power law) may describe the relationship between increasing dynamic Young's modulus E_{DYN} and decreasing full (static and anisotropic) log-based S_{HMIN} gradient prediction G_{SHMIN} can be described according to the equation:

$${G}_{SHMIN} = {A ( {E}_{DYN} )}^{- B} \qquad Eq . 6$$

and as shown in the example of FIG. 2A. Combining Eqs. 5 and 6 results in the following global predictive conditional relationship:

$$IF {V}_{CLAY} \leq {S}_{HMIN} = \frac{{v}_{DYN}}{1 - {v}_{DYN}} ( {S}_{OVB} - {P}_{RES} ) + {P}_{RES} + \frac{EC}{1 - {v}_{DYN}} , \text{} ELSE {S}_{HMIN} = {A ( {E}_{DYN} )}^{- B} \times TVD \qquad Eq . 7$$

where TVD refers to true vertical depth, E_{DYN}, ν_{DYN}, S_{OVB}, PRES and TVD are input parameters, A, B and C are calibration constants, and Θ represents a specific V_{CLAY} total clay volume content cutoff.

At block 108, a three-dimensional volume-based mechanical earth model is generated using the global predictive conditional relationship. For example, the S_{HMIN} estimate may be propagated in a 3D cellular model using the global calibration constants and the seismic facies as conditionals.

Those skilled in the art will appreciate that the exemplary method 100 of FIG. 1 is susceptible to modification without altering the technical effect provided by the present techniques. In practice, the exact manner in which the method 100 is implemented will depend, at least in part, on the details of the specific implementation. For example, in some embodiments, some of the blocks shown in FIG. 1 may be altered or omitted from the method 100 and/or new blocks may be added to the method 100.

FIG. 2A is a graph of a single function relationship between a log-derived static anisotropic S_{HMIN} gradient and a dynamic Young's modulus. In various aspects, a 1D well log analysis was performed to determine seismic calibration constants. As shown in both FIGS. 2A and 2B, lighter shading identifiers indicate increasing clay content. In particular, the coldest colors represent a total lack of clay while the hottest colors represent a clay content of 60%. In FIG. 2A, the horizontal axis of graph 200 represents Young's modulus E_{DYN} and the vertical axis represents the log-based S_{HMIN} gradient prediction G_{SHMIN}, as described in Eq. 6.

As shown in the graph 200A, the curve 202 represents a separation between facies with high clay content and facies with lower clay content, with higher clay content being to the left of curve 202 and lower clay content to the right of curve 202.

FIG. 2B is a graph of optimization of all calibration constants through linear regression. In the graph 200B of FIG. 2B, the horizontal axis represents synthetic S_{HMIN} profile and the vertical axis represents a log-based S_{HMIN} prediction

The curves 202 and 204 of FIGS. 2A and 2B are merely for purposes of illustration. In one or some embodiments, depending on the stress properties of a particular section of Earth being modeled, various different curves may be generated instead.

### 3D Model Propagation Techniques

While calibration and cutoff constants in Eq. 7 are derived solely from well log data using linear regression as shown in the example of FIG. 2B or any other complementary mathematical optimization techniques, once this log calibration step has been completed, Eq. 7 can be used to propagate horizontal principal stress magnitudes throughout an associated 3D MEM, where the input parameters are now derived from the geocellular model and the clay volume cutoff is replaced by either isotropic or anisotropic seismic facies, as described in FIG. 3.

FIG. 3 is a schematic view of an exemplary method for generating a three-dimensional geocellular model based on facies clay content in accordance with the present techniques. The example method 300 of FIG. 3 outlines an example workflow to calculate a synthetic S_{HMIN} profile 302 from Eqn. 7 in a three-dimensional geocellular mechanical earth model (3D MEM) 304. The method 300 populates the 3D MEM model 304 using as inputs 3D volumetric representations of the elastic properties, overburden stress 310, pore pressure 312, and seismic-inversion-based facies 314. The method 300 may begin at block 316, where the 3D log-based calculations are executed for the elastic moduli (E_{DYN} and ν_{DYN}). At block 318, the 1D log based elastic moduli are scaled up to the cell size of the geologic model 3D grid. In various embodiments, the cell-size could range from near log-scale to near seismic-scale, depending on the lateral region and depth range of interest.

Next, at block 320, a 3D seismic-scale elastic moduli (E_{DYN} and ν_{DYN}) calculation is calculated from the seismic inversion Vp/Vs and acoustic impedance (AI) volumes 308. Then, at block 322, the seismic-scale elastic moduli calculation is sampled into the geologic model 3D grid.

At block 324, a 3D pore pressure volume is likewise sampled into the model grid. For example, the 3D pore pressure volume may be sampled from a regional model of pore-pressure variation or local reservoir pressure measurements. A 3D overburden stress property is created in the MEM grid from an estimate of overburden gradient and the local depth below surface elevation.

At block 326, the 3D model properties for the elastic moduli are extrapolated away from the wells using the seismic-inversion based elastic moduli as a low-frequency guide. For example, one common modeling technique for this, sequential Gaussian inversion, uses co-kriging to honor well data locally and guides the propagation of the property away from the well using a seismic attribute property and a variogram. A correlation coefficient defines the relative weight of the log data and the seismic property. The relative weight of log-property versus seismic property could vary with seismic data quality or stratigraphic zones.

At block 302, S_{HMIN} is calculated at each 3D MEM cell location. The method 300 exploits the seismic inversion facies, also sampled into the model grid at block 328, as a proxy for clay content. The method 300 is given a choice of the simplified Isotropic (ISO) S_{HMIN} 330 or Anisotropic (ANI) S_{HMIN} 332, as described by Eq. 7. Here, as determined at decision diamond 334, clay-lean facies are assigned the ISO S_{HMIN} 332 solution and the clay-rich facies are assigned the ANI S_{HMIN} 330 solution. In this manner, every cell in the 3D MEM is populated with a single value of S_{HMIN}, without need for exact approximation of mineralogy or a Biot coefficient, and without need for a tectonic strain correction.

In various embodiments, the 3D MEM 304 yields 3D MEM products including 3D S_{HMIN} profiles 336 at any location away from data wells, 2D cross-sections, and maps or cross sections of S_{HMIN} 338 extracted by stratigraphic zones. In various embodiments, these 3D MEM products can then serve as inputs to different geomechanics-based tools and procedures to aid in development decisions. In some embodiments, the 3D MEM products may be input into a deterministic hydraulic fracture forward modeling at any location. In some embodiments, the 3D MEM products may be input into a deterministic hydraulic fracture forward modeling at any location, to predict the size of fractures and how the fractures might be constrained by different stress zones. As one example, experimental wells are sometimes used to collect information in experimental development programs, also referred to as pilots. In various examples, the 3D MEM products may be used to model how these fractures grow prior to the pilot program. After data is collected from the pilots, the data may be used to measure fracture size. The fracture models may then be compared to these data or diagnostic programs and ultimately used to make decisions, such as the well spacing. In addition, various models may be built. For example, a model may be built around an individual development, which might be a few miles. However, more regional models may also be built that would look at differences in stresses from one part to another within a development or between developments to provide more predictive solutions rather than measuring everything each time. The techniques described herein can thus be used to model fracture size and enable more predictive solution that is less reliant upon collection of a multitude of data from each individual development.

In some embodiments, the 3D MEM products may be used for assessing the lateral trends in stress within or between development areas. For example, such trends may be identified by analysis of maps 338. In some embodiments, the 3D MEM products may be inputs into a drilling or wellbore stability assessment. For example, the 3D MEM products may be used as inputs for determining drilling stability in conventional fields. In some embodiments, the 3D MEM products may be input into a determination of well landing zones. In some embodiments, the 3D MEM products may be input into may be input into an injection and topseal analysis. Top seal analysis is the evaluation of the formation integrity above the formation where the fluids are being injected. The injected fluids change the stress state, and potentially the hydrocarbon output. For example, the injection and topseal analysis may be performed for an enhanced oil recovery (EOR) or carbon storage. As one example, the 3D MEM products may be used to understand stresses that might be associated with increasing pore fluid pressure during injection.

Those skilled in the art will appreciate that the exemplary method 300 of FIG. 3 is susceptible to modification without altering the technical effect provided by the present techniques. In practice, the exact manner in which the method 300 is implemented will depend, at least in part, on the details of the specific implementation. For example, in some embodiments, some of the blocks shown in FIG. 3 may be altered or omitted from the method 300 and/or new blocks may be added to the method 300.

### Exemplary Cluster Computing System for Implementing Present Techniques

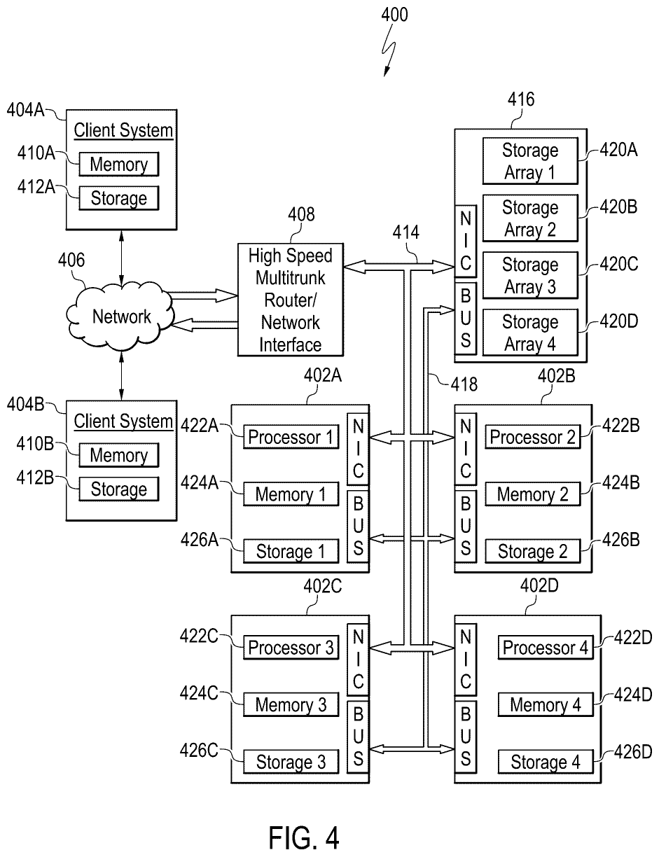

FIG. 4 is a block diagram of an exemplary cluster computing system 400 that may be utilized to implement the present techniques. The exemplary cluster computing system 400 shown in FIG. 4 has four computing units 402A, 402B, 402C, and 402D, each of which may perform calculations for a portion of the present techniques. However, one of ordinary skill in the art will recognize that the cluster computing system 400 is not limited to this configuration, as any number of computing configurations may be selected. For example, a smaller analysis may be run on a single computing unit, such as a workstation, while a large calculation may be run on a cluster computing system 400 having tens, hundreds, thousands, or even more computing units.

The cluster computing system 400 may be accessed from any number of client systems 404A and 404B over a network 406, for example, through a high-speed network interface 408. The computing units 402A to 402D may also function as client systems, providing both local computing support and access to the wider cluster computing system 400.

The network 406 may include a local area network (LAN), a wide area network (WAN), the Internet, or any combinations thereof. Each client system 404A and 404B may include one or more non-transitory, computer-readable storage media for storing the operating code and program instructions that are used to implement the present techniques. For example, each client system 404A and 404B may include a memory device 410A and 410B, which may include random access memory (RAM), read only memory (ROM), and the like. Each client system 404A and 404B may also include a storage device 412A and 412B, which may include any number of hard drives, optical drives, flash drives, or the like.

The high-speed network interface 408 may be coupled to one or more buses in the cluster computing system 400, such as a communications bus 414. The communication bus 414 may be used to communicate instructions and data from the high-speed network interface 408 to a cluster storage system 416 and to each of the computing units 402A to 402D in the cluster computing system 400. The communications bus 414 may also be used for communications among the computing units 402A to 402D and the cluster storage system 416. In addition to the communications bus 414, a high-speed bus 418 can be present to increase the communications rate between the computing units 402A to 402D and/or the cluster storage system 416.

The cluster storage system 416 can have one or more non-transitory, computer-readable storage media, such as storage arrays 420A, 420B, 420C and 420D for the storage of models, data (including core data relating to one or more wells), visual representations, results (such as graphs, charts, and the like used to convey results obtained using the present techniques), code, and other information concerning the implementation of the present techniques. The storage arrays 420A to 420D may include any combinations of hard drives, optical drives, flash drives, or the like.

Each computing unit 402A to 402D can have a processor 422A, 422B, 422C and 422D and associated local non-transitory, computer-readable storage media, such as a memory device 424A, 424B, 424C and 424D and a storage device 426A, 426B, 426C and 426D. Each processor 422A to 422D may be a multiple core unit, such as a multiple core central processing unit (CPU) or a graphics processing unit (GPU). Each memory device 424A to 424D may include ROM and/or RAM used to store program instructions for directing the corresponding processor 422A to 422D to implement the present techniques. Each storage device 426A to 426D may include one or more hard drives, optical drives, flash drives, or the like. In addition, each storage device 426A to 426D may be used to provide storage for models, intermediate results, data, images, or code associated with operations, including code used to implement the present techniques.

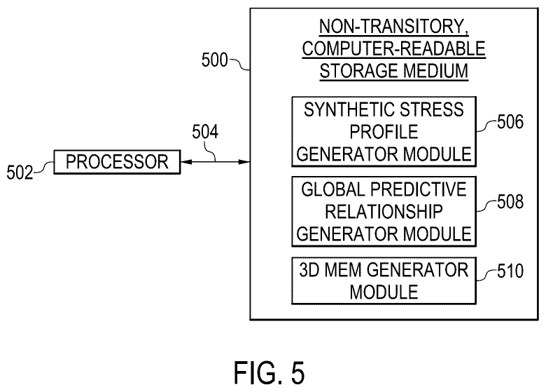

The present techniques are not limited to the architecture or unit configuration illustrated in FIG. 4. For example, any suitable processor-based device may be utilized for implementing all or a portion of embodiments of the present techniques, including without limitation personal computers, laptop computers, computer workstations, mobile devices, and multi-processor servers or workstations with (or without) shared memory. Moreover, embodiments may be implemented on application specific integrated circuits (ASICs) or very-large-scale integrated (VLSI) circuits. In fact, persons of ordinary skill in the art may utilize any number of suitable structures capable of executing logical operations according to embodiments described herein. FIG. 5 is a block diagram of an exemplary non-transitory, computer-readable storage medium 500 that may be used for the storage of data and modules of program instructions for implementing the present techniques. The non-transitory, computer-readable storage medium 500 may include a memory device, a hard disk, and/or any number of other devices, as described herein. A processor 502 may access the non-transitory, computer-readable storage medium 500 over a bus or network 504. While the non-transitory, computer-readable storage medium 500 may include any number of modules (and sub-modules) for implementing the present techniques, in some embodiments, the non-transitory, computer-readable storage medium 500 includes a synthetic stress profile generator module 506. More specifically, the synthetic stress profile generator module 506 may direct the processor 502 to generate a synthetic principal horizontal stress profile representative of a one-dimensional mechanical earth model (1D MEM) based on a simplification that all formations are elastically isotropic. For example, in some embodiments, the synthetic principal horizontal stress profile is a synthetic minimum principal horizontal stress profile. In some embodiments, the synthetic principal horizontal stress profile is a synthetic maximum principal horizontal stress profile. In addition, in some embodiments, the synthetic stress profile generator module 506 may direct the processor 502 to generate the synthetic principal horizontal stress profile based on an assumption that Biot's coefficient equals unity. Moreover, in some embodiments, the well calibration module 506 may direct the processor 502 to generate the synthetic principal horizontal stress profile further based on an assumption that minimum and maximum tectonic strains are equivalent. In some embodiments, the well calibration module 506 may direct the processor 502 to generate the synthetic principal horizontal stress profile based on a simplification that static properties are equivalent to dynamic properties.

Furthermore, in some embodiments, the non-transitory, computer-readable storage medium 500 includes a global predictive relationship generator module 508 for utilizing the output of the well calibration module 506 to combine the isotropically generated synthetic principal horizontal stress profile with an additional data-driven functional relationship for anisotropic formations to generate a global predictive conditional relationship based on a lithology dependent cutoff. In some embodiments, the additional data-driven functional relationship is an inverse power law. For example, the inverse power law describes a relationship between increasing dynamic Young's modulus and decreasing a full log-based S_{HMIN} gradient prediction. In some embodiments, the additional data-driven functional relationship is a polynomial. In various embodiments, the lithology dependent cutoff is a facies clay content threshold. In various embodiments, the global predictive conditional relationship employs viscoplastic theory, porolastic theory, or a combination thereof.

In addition, in some embodiments, the non-transitory, computer-readable storage medium 500 includes a three-dimensional mechanical earth model (3D MEM) generator module 510 for utilizing the output of the global predictive relationship generator module 508 to generate a three-dimensional volume-based mechanical earth model using the global predictive conditional relationship. In some embodiments, the 3D MEM generator module 508 may direct the processor 502 to generate a map of a synthetic principal horizontal stress profile. In some embodiments, the 3D MEM generator module 508 may direct the processor 502 to further generate a synthetic principal horizontal stress profile for a particular point in the 3D MEM. In some embodiments, the 3D MEM generator module 508 may direct the processor 502 to generating a cross section based on the synthetic principal horizontal stress profile. In some embodiments, the 3D MEM generator module 508 may direct the processor 502 to receive inputs comprising 3D volumetric representations of elastic properties, overburden stress, pore pressure, and seismic-inversion-based facies and generate a three-dimensional synthetic principal horizontal stress profile geomodel. In this manner, the techniques described herein provide a practical application that directly improves the efficiency and accuracy of modelling three dimensional earth models, such as those used in fracturing, injection, and carbon storage applications.

Although embodiments herein are described with respect to the unconventional oil extraction, one with skilled in the art will readily recognize that the techniques described herein are also suitable for application in other areas, such as injection or carbon storage. For example, such applications may include predicting a hydraulic fracture geometries and dimensions based on the 3D MEM. Other applications may include predicting mud weights for drilling stable wellbores.

It is intended that the foregoing detailed description be understood as an illustration of selected forms that the invention can take and not as a definition of the invention. It is only the following claims, including all equivalents which are intended to define the scope of the claimed invention. Further, it should be noted that any aspect of any of the preferred embodiments described herein may be used alone or in combination with one another. Finally, persons skilled in the art will readily recognize that in preferred implementation, some, or all of the steps in the disclosed method are performed using a computer so that the methodology is computer implemented. In such cases, the resulting 3D MEM may be downloaded or saved to computer storage.

### Embodiments of Present Techniques

In one or more embodiments, the present techniques may be susceptible to various modifications and alternative forms, such as the following embodiments as noted in paragraphs 1 to 28:

1. A method for calibrating three-dimensional earth models, wherein the method is executed via a processor of a computing system, and wherein the method comprises: generating a synthetic principal horizontal stress profile representative of a one-dimensional mechanical earth model (1D MEM) based on a simplification that all formations are elastically isotropic; combining the isotropically generated synthetic principal horizontal stress profile with an additional data-driven functional relationship for anisotropic formations to generate a global predictive conditional relationship based on a lithology dependent cutoff; and generating a three-dimensional volume-based mechanical earth model using the global predictive conditional relationship.
2. The method of paragraph 1, wherein the synthetic principal horizontal stress profile is a synthetic minimum principal horizontal stress profile.
3. The method of paragraphs 1 or 2, wherein the synthetic principal horizontal stress profile is a synthetic maximum principal horizontal stress profile.
4. The method of any of paragraphs 1 to 3, wherein generating the synthetic principal horizontal stress profile is further based on an assumption that Biot's coefficient equals unity.
5. The method of any of paragraphs 1 to 4, wherein generating the synthetic principal horizontal stress profile is further based on an assumption that minimum and maximum tectonic strains are equivalent.
6. The method of any of paragraphs 1 to 5, wherein generating the synthetic principal horizontal stress profile is further based on a simplification that static properties are equivalent to dynamic properties
7. The method of any of paragraphs 1 to 6, wherein the additional data-driven functional relationship is an inverse power law.
8. The method of paragraph 7, wherein the inverse power law describes a relationship between increasing dynamic Young's modulus and decreasing a full log-based synthetic principal horizontal stress profile gradient prediction.
9. The method of any of paragraphs 1 to 8, wherein the additional data-driven functional relationship is a polynomial.
10. The method of any of paragraphs 1 to 9, wherein the lithology dependent cutoff comprises a facies clay content threshold.
11. The method of any of paragraphs 1 to 10, comprising generating a map of a synthetic principal horizontal stress profile.
12. The method of any of paragraphs 1 to 11, comprising generating a synthetic principal horizontal stress profile for a particular point in the 3D MEM.
13. The method of any of paragraphs 1 to 12, comprising generating a cross section based on the synthetic principal horizontal stress profile.
14. The method of any of paragraphs 1 to 13, comprising predicting hydraulic fracture geometries and dimensions based on the 3D MEM.
15. The method of any of paragraphs 1 to 14, comprising predicting mud weights for drilling stable wellbores.
16. The method of any of paragraphs 1 to 15, wherein the global predictive conditional relationship employs viscoplastic theory, porolastic theory, or a combination thereof.
17. The method of any of paragraphs 1 to 16, comprising receiving inputs comprising 3D volumetric representations of elastic properties, overburden stress, pore pressure, and seismic-inversion-based facies and generating a three dimensional synthetic principal horizontal stress profile geomodel.
18. A method for generating and propagating synthetic stress profiles, wherein the method is executed via a processor of a computing system, and wherein the method comprises: generating a synthetic principal horizontal stress profile representative of a one-dimensional mechanical earth model (1D MEM) based on a simplification that all formations are elastically isotropic; combining the isotropically generated synthetic principal horizontal stress profile with an additional data-driven functional relationship for anisotropic formations to generate a global predictive conditional relationship based on a lithology dependent cutoff; and propagating the isotropically generated synthetic principal horizontal stress profile through a 3D geocellular model based on the global predictive conditional relationship to generate a 3D synthetic principal horizontal stress profile geomodel.
19. The method of paragraph 18, wherein propagating the isotropically generated synthetic principal horizontal stress profile through a 3D geocellular model comprises using global calibration constants and seismic facies as conditionals.
20. The method of paragraph 19, wherein a cell of the 3D synthetic minimum principal horizontal stress profile geomodel is modeled using an isotropic component in response to detecting that the cell is associated with clay content that exceeds a total clay volume content cutoff threshold.
21. The method of paragraph 19, wherein a cell of the 3D synthetic minimum principal horizontal stress profile geomodel is modeled using an anisotropic component in response to detecting that the cell is associated with clay content that does not exceed a total clay volume content cutoff threshold.
22. The method of any of paragraphs 18 to 21, comprising executing 3D log-based calculations for elastic moduli and upscaling the 1D log based elastic moduli up to a cell size of a geologic model 3D grid.
23. The method of any of paragraphs 18 to 22, comprising calculating a 3D seismic-sale elastic moduli calculation from seismic inversion and acoustic impedance volumes and sampling the calculation into a geologic model 3D grid.
24. The method of paragraph 23, comprising extrapolating 3D model properties for elastic moduli away from wells using the seismic-inversion based elastic moduli as a low-frequency guide.
25. The method of any of paragraphs 18 to 24, comprising sampling a 3D pore pressure and seismic-inversion facies into a geologic model 3D grid.
26. The method of any of paragraphs 18 to 25, further comprising generating a map of the 3D synthetic minimum principal horizontal stress profile geomodel, wherein the map is extracted by a stratigraphic zone.
27. The method of any of paragraphs 18 to 26, further comprising generating a synthetic minimum principal horizontal stress profile for a particular point of the 3D synthetic minimum principal horizontal stress profile geomodel.
28. The method of any of paragraphs 18 to 27, further comprising generating a two-dimensional cross-section of the 3D synthetic minimum principal horizontal stress profile geomodel.

While the embodiments described herein are well-calculated to achieve the advantages set forth, it will be appreciated that such embodiments are susceptible to modification, variation, and change without departing from the spirit thereof. In other words, the particular embodiments described herein are illustrative only, as the teachings of the present techniques may be modified and practiced in different but equivalent manners apparent to those skilled in the art having the benefit of the teachings herein. Moreover, the systems and methods illustratively disclosed herein may suitably be practiced in the absence of any element that is not specifically disclosed herein and/or any optional element disclosed herein. While compositions and methods are described in terms of “comprising” or “including” various components or steps, the compositions and methods can also “consist essentially of” or “consist of” the various components and steps. Indeed, the present techniques include all alternatives, modifications, and equivalents falling within the true spirit and scope of the appended claims.

What is claimed is:

1. A method for calibrating three-dimensional earth models, wherein the method is executed via a processor of a computing system, and wherein the method comprises:
generating a synthetic principal horizontal stress profile representative of a one-dimensional mechanical earth model (1D MEM) based on a simplification that all formations are elastically isotropic;
combining the isotropically generated synthetic principal horizontal stress profile with an additional data-driven functional relationship for anisotropic formations to generate a global predictive conditional relationship based on a lithology dependent cutoff; and
generating a three-dimensional volume-based mechanical earth model using the global predictive conditional relationship.

2. The method of claim 1, wherein the synthetic principal horizontal stress profile is a synthetic minimum principal horizontal stress profile.

3. The method of claim 1, wherein the synthetic principal horizontal stress profile is a synthetic maximum principal horizontal stress profile.

4. The method of claim 1, wherein generating the synthetic principal horizontal stress profile is further based on an assumption that Biot's coefficient equals unity.

5. The method of claim 1, wherein generating the synthetic principal horizontal stress profile is further based on an assumption that minimum and maximum tectonic strains are equivalent.

6. The method of claim 1, wherein generating the synthetic principal horizontal stress profile is further based on a simplification that static properties are equivalent to dynamic properties.

7. The method of claim 1, wherein the additional data-driven functional relationship is an inverse power law.

8. The method of claim 7, wherein the inverse power law describes a relationship between increasing dynamic Young's modulus and decreasing a full log-based synthetic principal horizontal stress profile gradient prediction.

9. The method of claim 1, wherein the additional data-driven functional relationship is a polynomial.

10. The method of claim 1, wherein the lithology dependent cutoff comprises a facies clay content threshold.

11. The method of claim 1, comprising generating a map of a synthetic principal horizontal stress profile.

12. The method of claim 1, comprising generating a synthetic principal horizontal stress profile for a particular point in the 3D MEM.

13. The method of claim 1, comprising generating a cross section based on the synthetic principal horizontal stress profile.

14. The method of claim 1, comprising predicting hydraulic fracture geometries and dimensions based on the 3D MEM.

15. The method of claim 1, comprising predicting mud weights for drilling stable wellbores.

16. The method of claim 1, wherein the global predictive conditional relationship employs viscoplastic theory, porolastic theory, or a combination thereof.

17. The method of claim 1, comprising receiving inputs comprising 3D volumetric representations of elastic properties, overburden stress, pore pressure, and seismic-inversion-based facies and generating a three dimensional synthetic principal horizontal stress profile geomodel.

18. A method for generating and propagating synthetic stress profiles, wherein the method is executed via a processor of a computing system, and wherein the method comprises:
generating a synthetic principal horizontal stress profile representative of a one-dimensional mechanical earth model (1D MEM) based on a simplification that all formations are elastically isotropic;
combining the isotropically generated synthetic principal horizontal stress profile with an additional data-driven functional relationship for anisotropic formations to generate a global predictive conditional relationship based on a lithology dependent cutoff; and
propagating the isotropically generated synthetic principal horizontal stress profile through a 3D geocellular model based on the global predictive conditional relationship to generate a 3D synthetic principal horizontal stress profile geomodel.

19. The method of claim 18, wherein propagating the isotropically generated synthetic principal horizontal stress profile through a 3D geocellular model comprises using global calibration constants and seismic facies as conditionals.

20. The method of claim 19, wherein a cell of the 3D synthetic minimum principal horizontal stress profile geomodel is modeled using an isotropic component in response to detecting that the cell is associated with clay content that exceeds a total clay volume content cutoff threshold.

21. The method of claim 19, wherein a cell of the 3D synthetic minimum principal horizontal stress profile geomodel is modeled using an anisotropic component in response to detecting that the cell is associated with clay content that does not exceed a total clay volume content cutoff threshold.

22. The method of claim 18, comprising executing 3D log-based calculations for elastic moduli and upscaling the 1D log based elastic moduli up to a cell size of a geologic model 3D grid.

23. The method of claim 18, comprising calculating a 3D seismic-sale elastic moduli calculation from seismic inversion and acoustic impedance volumes and sampling the calculation into a geologic model 3D grid.

24. The method of claim 23, comprising extrapolating 3D model properties for elastic moduli away from wells using the seismic-inversion based elastic moduli as a low-frequency guide.

25. The method of claim 18, comprising sampling a 3D pore pressure and seismic-inversion facies into a geologic model 3D grid.

26. The method of claim 18, further comprising generating a map of the 3D synthetic minimum principal horizontal stress profile geomodel, wherein the map is extracted by a stratigraphic zone.

27. The method of claim 18, further comprising generating a synthetic minimum principal horizontal stress profile for a particular point of the 3D synthetic minimum principal horizontal stress profile geomodel.

28. The method of claim 18, further comprising generating a two-dimensional cross-section of the 3D synthetic minimum principal horizontal stress profile geomodel.
